(19) United States
(12) Patent Application Publication
(10) Pub. No.: US 2022/0384543 A1
(43) Pub. Date: Dec. 1, 2022

(54) LIGHT EMITTING DEVICE

(71) Applicant: Au Optronics Corporation, Hsinchu (TW)

(72) Inventors: Qian-Wei Lin, Hsinchu (TW); Chien-Chuan Chen, Hsinchu (TW)

(73) Assignee: Au Optronics Corporation, Hsinchu (TW)

(21) Appl. No.: 17/393,403

(22) Filed: Aug. 4, 2021

(30) Foreign Application Priority Data
May 27, 2021 (TW) 110119209

(51) Int. Cl. H01L 27/32; H01L 51/52

(52) U.S. Cl. CPC H01L 27/3246; H01L 51/5259

(57) ABSTRACT

A light-emitting device includes a substrate, an active device layer, a bank structure and organic light-emitting materials. The active device layer is located on the substrate. The bank structure is located on the active device layer. The bank structure includes at least one first bank and a plurality of second banks. The at least one first bank has arc surfaces and includes hydrophilic materials. The second banks extend along the first direction, and the second banks include a hydrophobic material. The bank structure has a plurality of openings. Two sides of each opening are defined by two corresponding arc surfaces of the at least one first bank, and the other two sides of each opening are defined by two opposite side walls of the corresponding two second banks. The organic light-emitting materials are filled into the openings of the bank structure.

### CROSS-REFERENCE TO RELATED APPLICATION

This application claims the priority benefit of Taiwan application serial no. 110119209, filed on May 27, 2021. The entirety of the above-mentioned patent application is hereby incorporated by reference herein and made a part of this specification.

### BACKGROUND

### Technical Field

The present invention relates to a light-emitting device, and more particularly to a light-emitting device including an organic light-emitting material.

### Description of Related Art

Organic Light-Emitting Diode (OLED) is an electroluminescent semiconductor device, which has the advantages of high efficiency, long life time, not easy to break, fast response, high reliability, and etc. Compared with the traditional liquid crystal display device, the OLED display device does not need to be additionally provided with a backlight module, thereby reducing the thickness of the OLED display device. Based on the aforementioned advantages, OLED display devices are extremely competitive in the market.

Currently, common manufacturing methods of OLED include vapor deposition, coating, inkjet and so on. As consumers have higher and higher demand for image resolution, the process accuracy of organic light-emitting materials has also become higher and higher. When depositing the organic light-emitting material, if the organic light-emitting material cannot be uniformly distributed, the displayed image may not achieve the expected quality.

### SUMMARY

The invention provides a light-emitting device, which can improve the problem of poor wetting of organic light-emitting materials and banks.

At least one embodiment of the present invention provides a light-emitting device including a substrate, an active device layer, a bank structure, and a plurality of organic light-emitting materials. The active device layer is located on the substrate. The bank structure is located on the active device layer. The bank structure includes at least one first bank and a plurality of second banks. The first bank has a plurality of arc surfaces and includes hydrophilic materials. The second banks extend along a first direction, and the second banks include a hydrophobic material. The first bank partially overlaps the second banks. The bank structure has multiple openings. Two sides of each opening are defined by two corresponding arc surfaces of the first bank, and the other two sides of each opening are defined by two opposite side walls of the corresponding two second banks. The organic light-emitting materials are filled into the openings of the bank structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 3A are schematic top views of a method of manufacturing a light emitting device according to an embodiment of the invention.

FIG. 1B to FIG. 3B are schematic cross-sectional views taken along the line A-A′ of FIG. 1A to FIG. 3A, respectively.

FIG. 1C to FIG. 3C are schematic cross-sectional views taken along the line B-B′ of FIG. 1A to FIG. 3A, respectively.

FIG. 1D to FIG. 3D are schematic cross-sectional views taken along the line C-C′ of FIG. 1A to FIG. 3A, respectively.

FIG. 4 to FIG. 6A are schematic top views of a method of manufacturing a light-emitting device according to an embodiment of the present invention.

FIG. 6B is a schematic cross-sectional view taken along line A-A′ of FIG. 6A.

FIG. 6C is a schematic cross-sectional view taken along line B-B′ of FIG. 6A.

FIG. 6D is a schematic cross-sectional view taken along line C-C′ of FIG. 6A.

### DESCRIPTION OF THE EMBODIMENTS

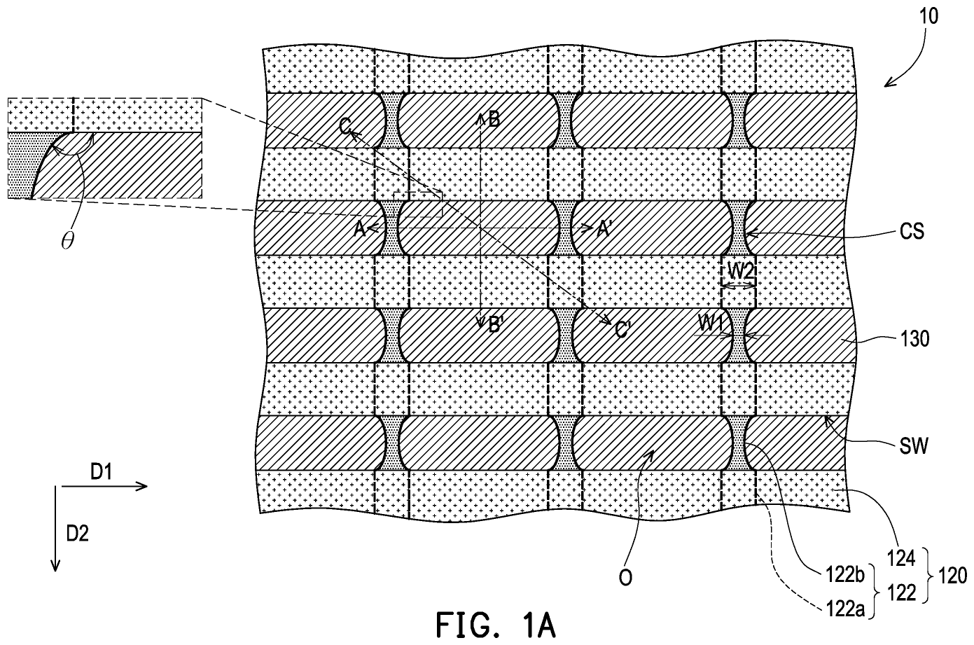

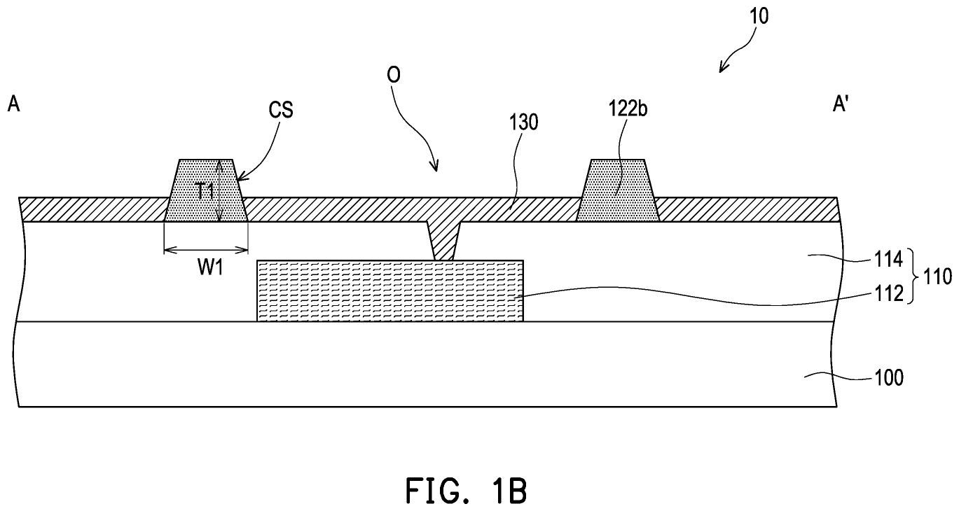

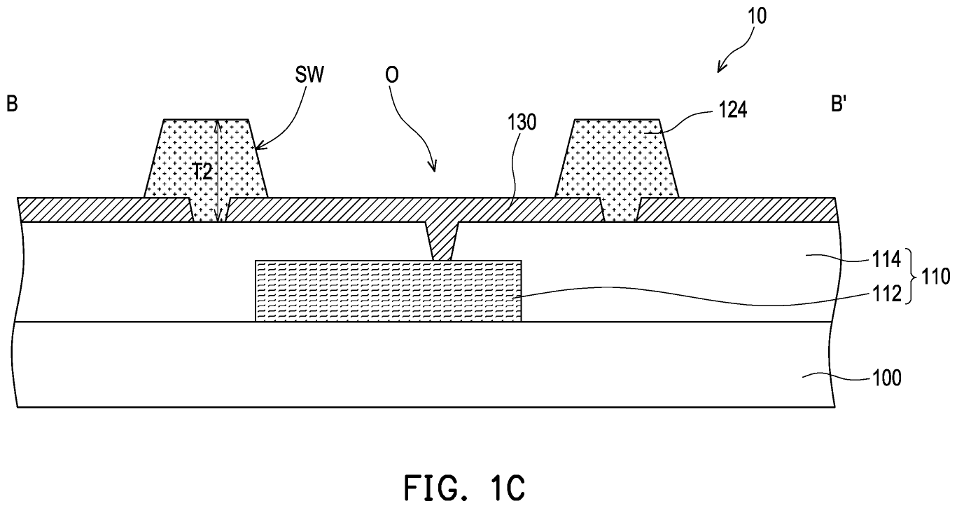

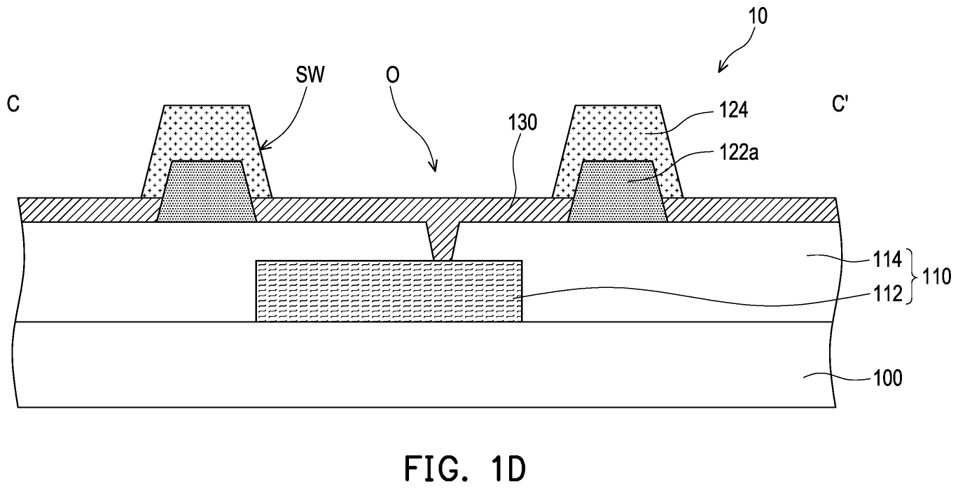

FIG. 1A to FIG. 3A are schematic top views of a method of manufacturing a light emitting device according to an embodiment of the invention. FIG. 1B to FIG. 3B are schematic cross-sectional views taken along the line A-A′ of FIG. 1A to FIG. 3A, respectively. FIG. 1C to FIG. 3C are schematic cross-sectional views taken along the line B-B′ of FIG. 1A to FIG. 3A, respectively. FIG. 1D to FIG. 3D are schematic cross-sectional views taken along the line C-C′ of FIG. 1A to FIG. 3A, respectively.

Referring to FIG. 1A to FIG. 1D, an active device substrate 10 is provided. The active device substrate 10 includes a substrate 100, an active device layer 110 and a bank structure 120. In this embodiment, the active device substrate 10 further includes a plurality of first electrodes 130.

The active device layer 110 is located on the substrate 100. In this embodiment, the active device layer 110 includes a plurality of active devices 112 and an insulating layer 114. The active elements 112 are, for example, thin film transistors. The insulating layer 114 is, for example, a single-layer or multi-layer structure, and the insulating layer 114 is located on the active devices 112.

The first electrodes 130 are located on the active device layer 110 and is electrically connected to the active device layer 110. In this embodiment, each first electrode 130 is respectively electrically connected to a corresponding active device 112.

The bank structure 120 is located on the active device layer 110. The bank structure 120 includes at least one first bank 122 and a plurality of second banks 124. In this embodiment, the bank structure 120 includes a plurality of first banks 122 and a plurality of second banks 124. The second banks 124 and the first banks 122 are respectively extending along a first direction D1 and a second direction D2

The first banks 122 are located on the insulating layer 114 of the active device layer 110. In this embodiment, opposite sides of the first bank 122 have a plurality of corresponding arc surfaces CS. Each first bank 122 partially overlaps the plurality of second banks 124. In this embodiment, each first bank 122 includes alternately arranged extension portions 122a and arc surface portions 122b. The extension portions 122a overlap the corresponding second banks 124, and each arc surface portion 122b is located between two adjacent extension portions 122a. The opposite sides of each arc surface 122b are arc surfaces CS. The minimum width W1 of each first bank 122 at the position corresponding to the arc surfaces CS is smaller than the minimum width W2 of each first bank 122 at the position overlapping the second banks 124. In other words, the minimum width W1 of the arc surface portion 122b is smaller than the minimum width W2 of the extension portion 122a.

The second bank 124 is located on the first bank 122 and on the insulating layer 114 of the active device layer 110. In this embodiment, each second bank 124 cross the extension portions 122a of a plurality of first banks 122 and contacts the side surfaces and top surfaces of the extension portions 122a.

In this embodiment, the first banks 122 contacts the side surfaces of the first electrodes 130, but the invention is not limited thereto. In this embodiment, part of the second banks 124 contacts the side surfaces of the first electrodes 130 and extends to the top surfaces of the first electrodes 130, but the invention is not limited thereto. Part of the first banks 122 and part of the second banks 124 fill the gap between the first electrodes 130.

In some embodiments, the thickness T2 of the second banks 124 is greater than the thickness T1 of the first banks 122. For example, the thickness T2 of the second banks 124 is greater than 1 micrometer, and the thickness T1 of the first bank 122 is less than 1 micrometer.

The bank structure 120 has a plurality of openings 0, and each first electrode 130 is located at the bottom of a corresponding opening 0 of the bank structure 120. Two sides of each opening 0 are defined by two corresponding arc surfaces CS of at least one first bank 122. In this embodiment, two sides of each opening 0 are defined by two corresponding arc surfaces CS of two adjacent first banks 122. The other two sides of each opening 0 are defined by the two opposite side walls SW of two corresponding second banks 124. In each opening 0, the included angles 0 between the two corresponding arc surfaces CS and the two opposite side walls SW of the two corresponding second banks 124 are greater than 90 degrees.

In this embodiment, the material of the first banks 122 is different from the material of the second banks 124. For example, the first banks 122 include a hydrophilic material, and the second banks 124 includes a hydrophobic material. In some embodiments, the material of the first banks 122 include a cured positive photoresist, and the material of the second banks 124 include a cured negative photoresist.

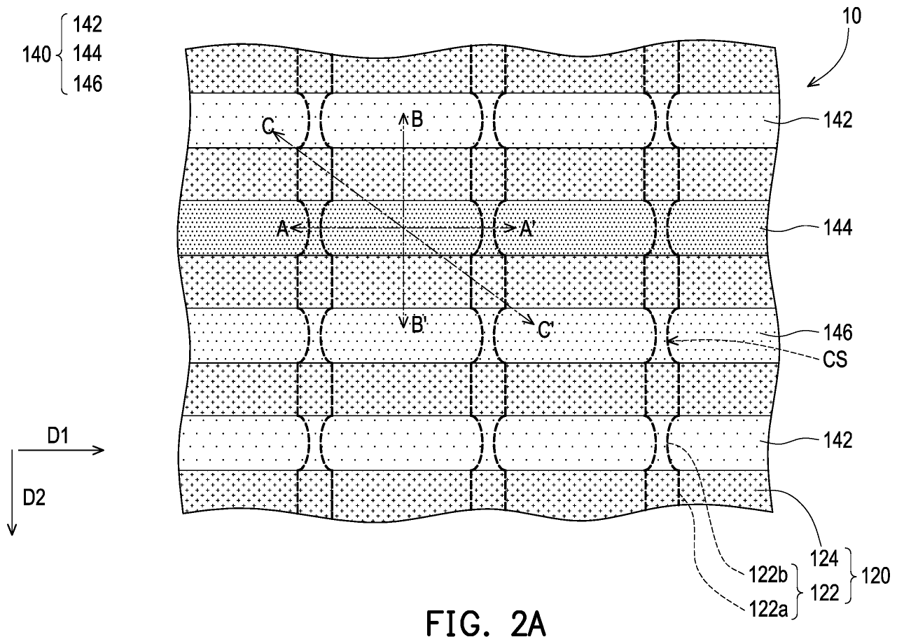

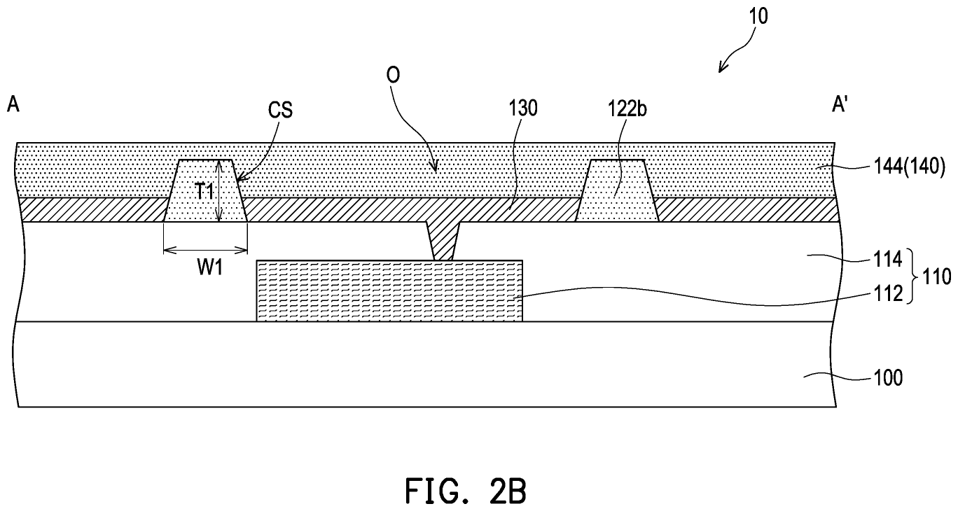

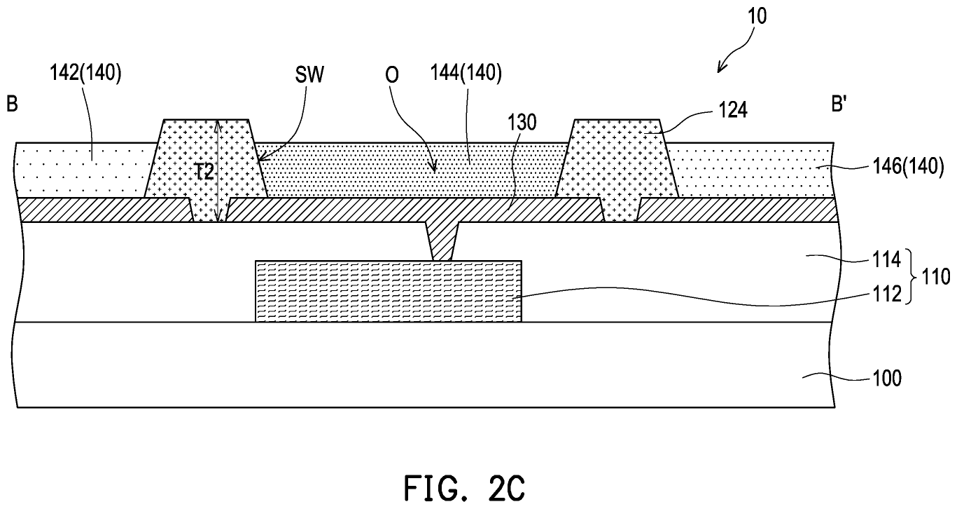

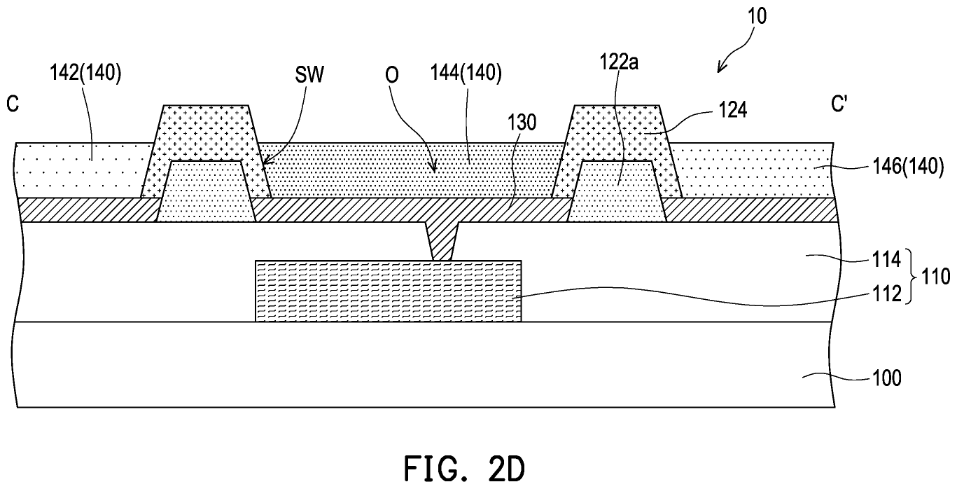

FIG. 2A to FIG. 2D, a plurality of organic light emitting materials 140 are formed on the first electrodes 130. In this embodiment, the organic light-emitting materials 140 are filled in the openings 0 of the bank structure 120.

In this embodiment, the organic light emitting materials 140 include a first organic light emitting material 142, a second organic light emitting material 144, and a third organic light emitting material 146. The first organic light-emitting material 142, the second organic light-emitting material 144, and the third organic light-emitting material 146 extend along the first direction D1, and the organic light-emitting materials 140 between two adjacent second banks 124 have the same color. The first organic light emitting material 142, the second organic light emitting material 144, and the third organic light emitting material 146 are arranged along the second direction D2, and the first organic light emitting material 142, the second organic light emitting material 144, and the third organic light emitting material 146 arranged along the second direction D2 are separated from each other. In some embodiments, the method of forming the organic light-emitting materials 140 include inkjet printing. For example, the organic light emitting materials 140 are formed in the opening 0 by nozzles. In some embodiments, the aforementioned nozzles move along the first direction D1, so that the organic light-emitting materials 140 of the same color extend along the first direction D1. In some embodiments, the first organic light-emitting material 142, the second organic light-emitting material 144, and the third organic light-emitting material 146 are, for example, a red organic light-emitting material, a green organic light-emitting material, and a blue organic light-emitting material, respectively, but the invention is not limited thereto. In other embodiments, the first organic light-emitting material 142, the second organic light-emitting material 144, and the third organic light-emitting material 146 may also be organic light-emitting materials of other colors.

In this embodiment, the first organic light-emitting material 142, the second organic light-emitting material 144, and the third organic light-emitting material 146 extend along the first direction D1, and each of the first organic light-emitting material 142, the second organic light-emitting material 144, and the third organic light-emitting material 146 cross the arc surface portions 122b of the plurality of first banks 122. In this embodiment, since the first banks 122 include a hydrophilic material, the organic light-emitting materials 140 of the same color can easily cross the first banks 122. At the same time, since the second banks 124 include a hydrophobic material, the organic light emitting materials 140 of different colors cannot easily cross the second banks 124, so that the organic light emitting materials 140 of different colors are not easily mixed with each other.

In this embodiment, the wetting effect of the organic light emitting materials 140 and the bank structure 120 can be improved by the arrangement of the arc surfaces CS. Specifically, with the arrangement of the arc surfaces CS, the problem that the angle between the first bank 122 and the second bank 124 is too small can be improved, thereby avoiding the problem that the organic light emitting materials 140 is difficult to fill the angle between the first bank 122 and the second bank 124.

Although in the drawings of this embodiment, each of the first organic light-emitting material 142, the second organic light-emitting material 144, and the third organic light-emitting material 146 is shown in a single-layer structure, but the invention is not limited thereto. In some embodiments, each of the first organic light emitting material 142, the second organic light emitting material 144, and the third organic light emitting material 146 includes a multilayer structure.

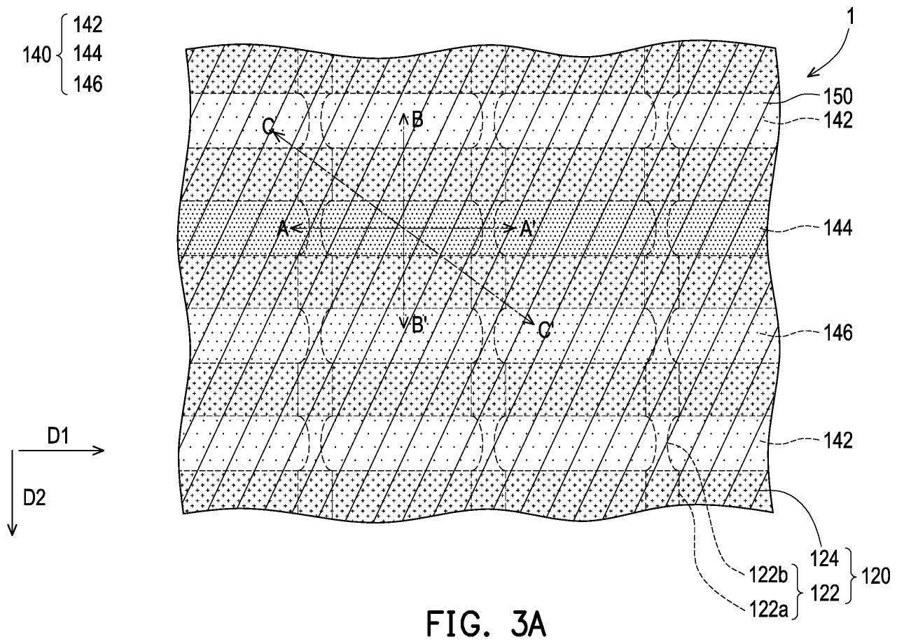

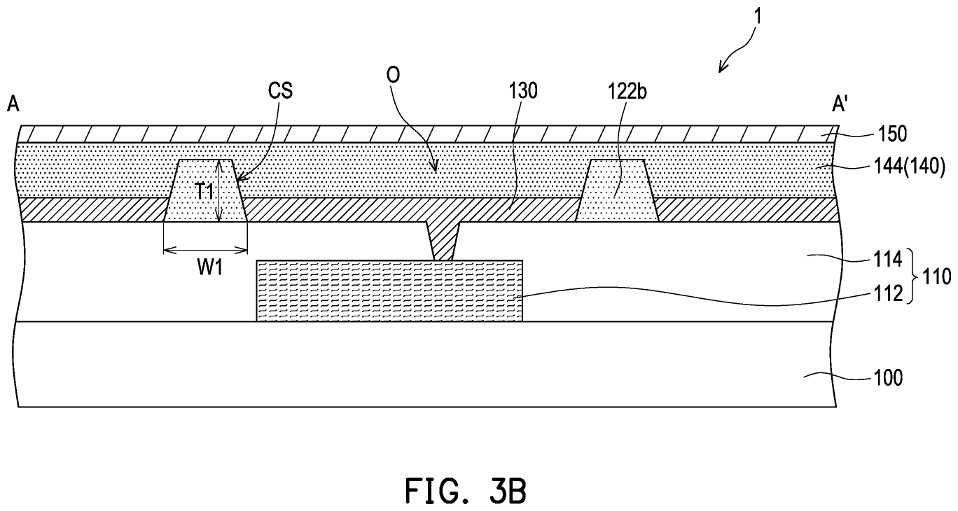

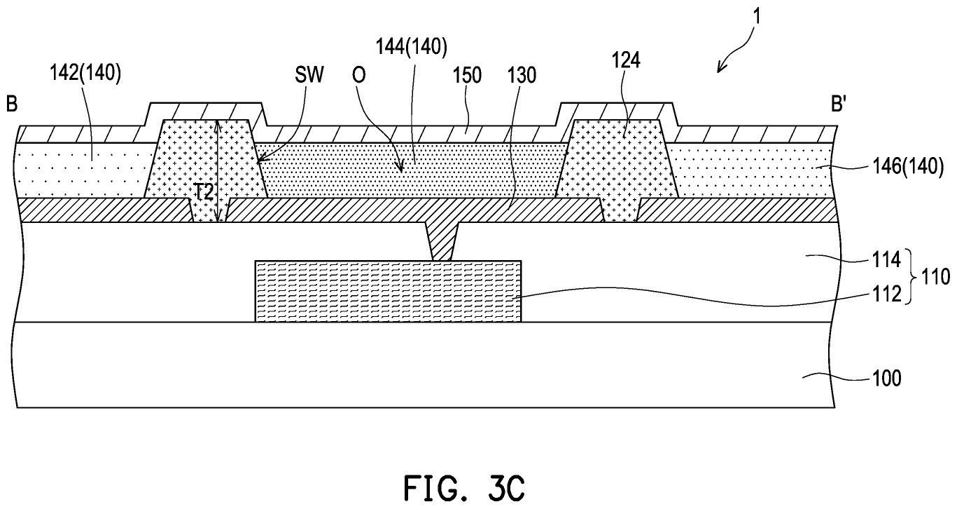

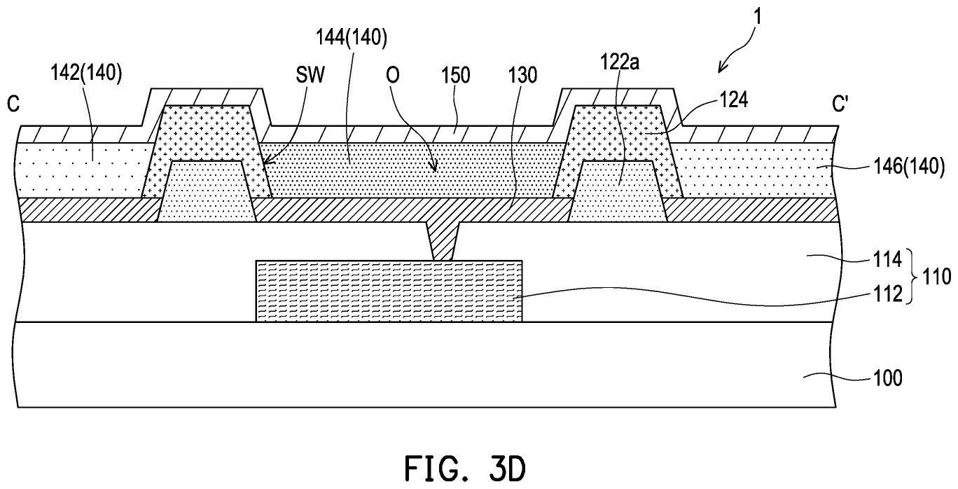

Referring to FIG. 3A to FIG. 3D, a second electrode 150 is formed on the organic light-emitting materials 140. So far, the light-emitting device 1 is substantially completed.

In this embodiment, the second electrode 150 is located on the organic light-emitting materials 140 and on the second banks 124. In some embodiments, at least one of the first electrodes 130 and the second electrode 150 is a transparent electrode, so that the light emitted by the organic light-emitting materials 140 can pass through the first electrodes 130 and/or the second electrode 150.

Based on the above, the arc surfaces CS are beneficial to improve the wetting effect of the organic light-emitting materials 140 and the bank structures 120, thereby increasing the uniformity of the organic light-emitting materials 140 and improving the display efficacy of the light-emitting device 1.

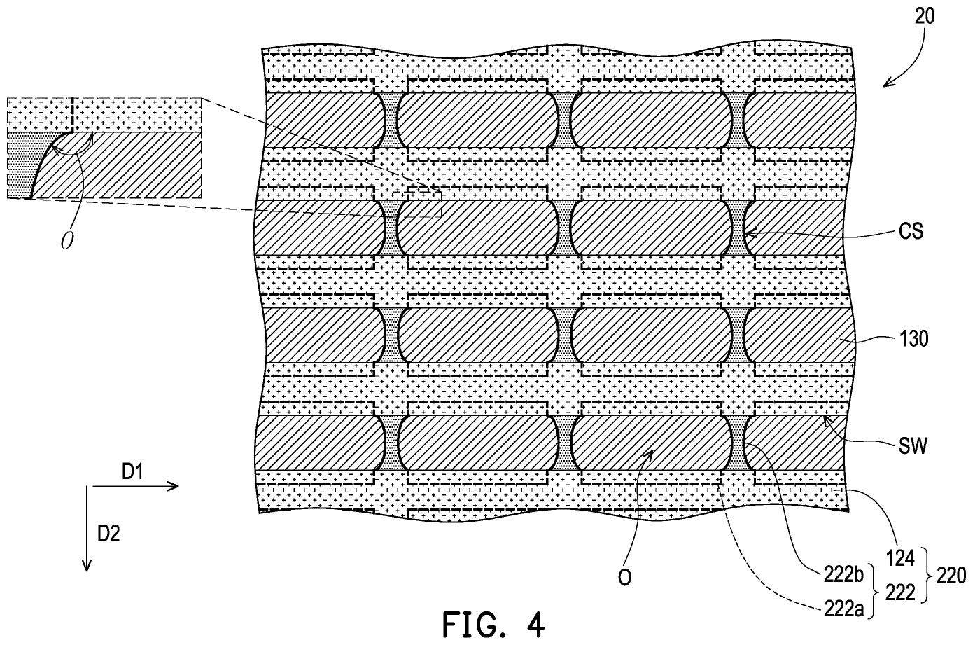

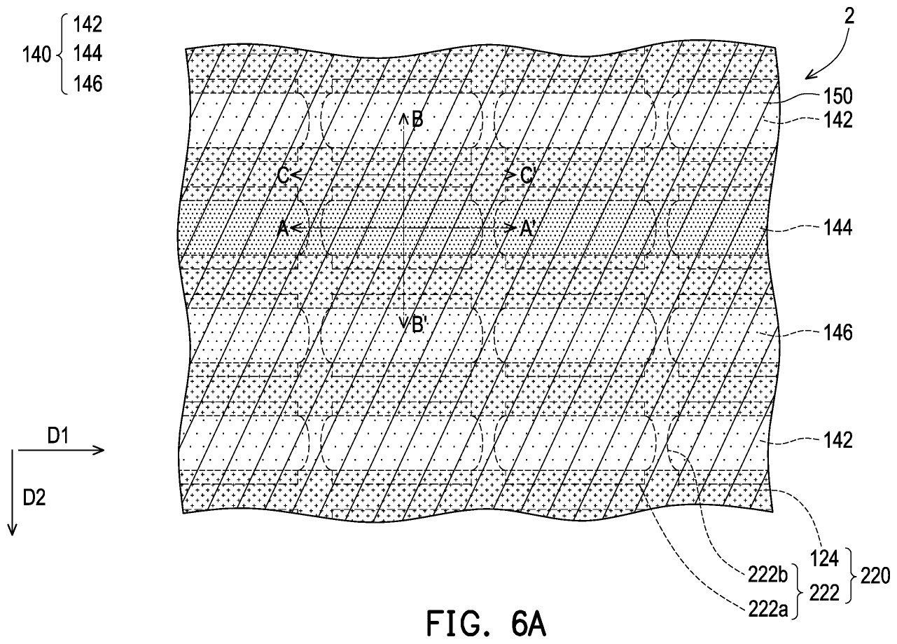

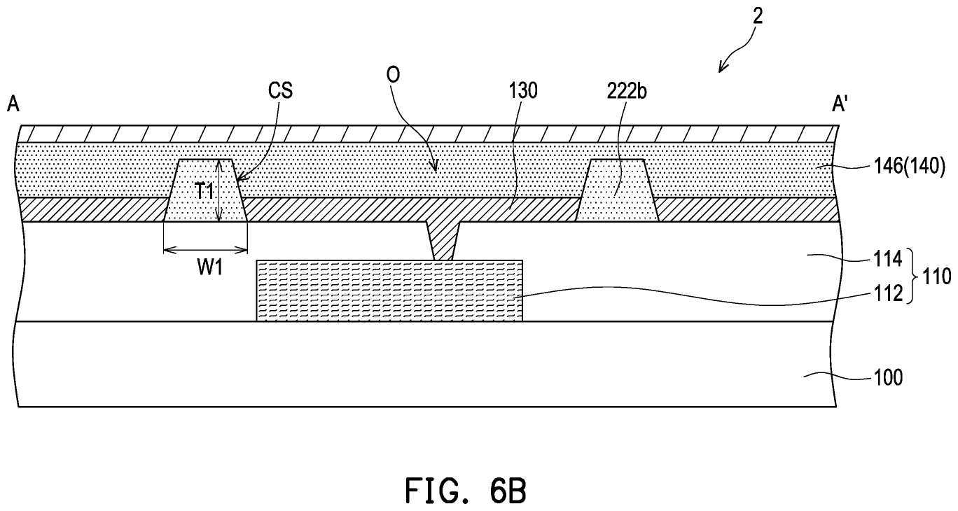

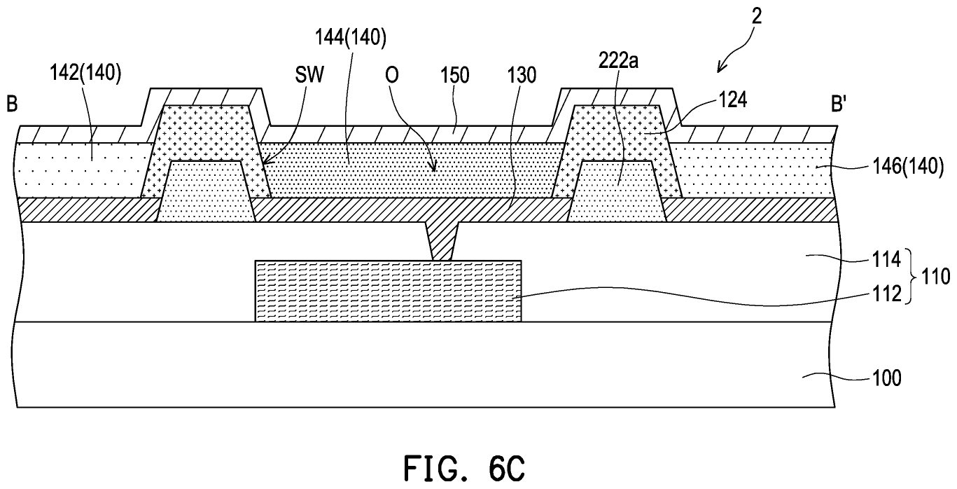

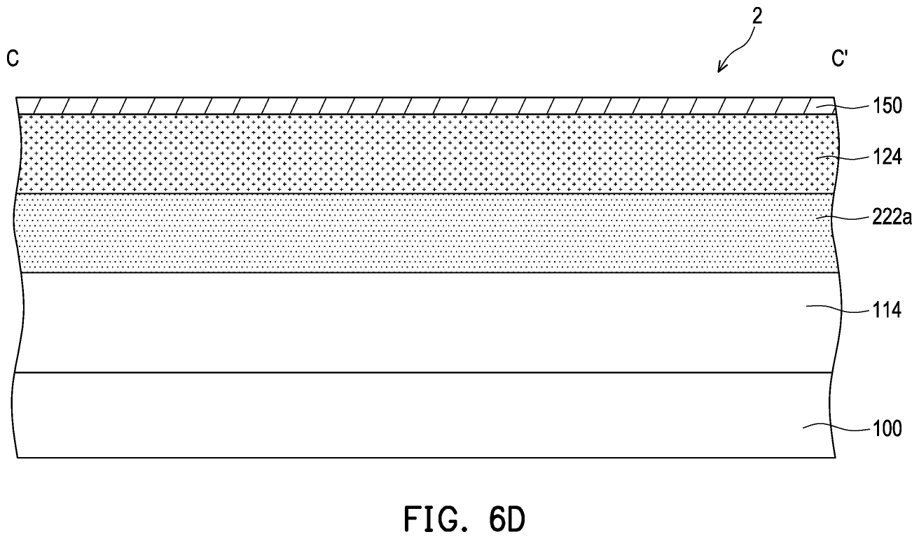

FIG. 4 to FIG. 6A are schematic top views of a method of manufacturing a light-emitting device according to an embodiment of the present invention. FIG. 6B is a schematic cross-sectional view taken along line A-A′ of FIG. 6A. FIG. 6C is a schematic cross-sectional view taken along line B-B′ of FIG. 6A. FIG. 6D is a schematic cross-sectional view taken along line C-C′ of FIG. 6A.

It must be noted here that the embodiment of FIG. 4 to FIG. 6D follows the reference numerals and partial contents of the embodiment of FIG. 1A to FIG. 3D, wherein the same or similar components are denoted by the same or similar reference numerals, and the description of the same technical content is omitted. For the description of the omitted parts, reference may be made to the foregoing embodiments and will not be repeated in the following embodiments.

Referring to FIG. 4, an active device substrate 20 is provided. The active device substrate 20 includes a substrate 100, an active device layer 110 and a bank structure 220. In this embodiment, the active device substrate 20 further includes a plurality of first electrodes 130.

The active device layer 110 is located on the substrate 100. In this embodiment, the active device layer 110 includes a plurality of active devices 112 and an insulating layer 114.

The first electrodes 130 are located on the active device layer 110 and are electrically connected to the active device layer 110.

The bank structure 220 is located on the active device layer 110. The bank structure 220 includes a first bank 222 and a plurality of second banks 124. In this embodiment, the first bank 222 is a continuous mesh structure, and the first bank 222 includes a plurality of extension portions 222a extending along the first direction D1 and a plurality of extension portions 222b extending along the second direction D2, wherein a plurality of arc surface portions 222b arranged along the first direction D1 are between two adjacent rows of extension portions 222a, and the extension portions 222a is connected to the extension portion 222a. The second bank 124 extend along the first direction D1.

The first bank 222 is located on the insulating layer 114 of the active device layer 110. The extension portions 222a of the first bank 222 are overlapping with the second bank 124. In this embodiment, the arc surface portions 222b of the first bank 222 has a plurality of arc surfaces CS. The opposite sides of each arc surface portion 222b are arc surfaces CS.

The second banks 124 are located on the first bank 222 and on the insulating layer 114 of the active device layer 110. In this embodiment, each second bank 124 is in contact with the side surfaces and the top surfaces of the extension portions 222a.

In this embodiment, the first bank 222 is in contact with the side surfaces of the first electrodes 130, but the invention is not limited thereto. In this embodiment, part of the second banks 124 is in contact with the side surfaces of the first electrodes 130 and extends to the top surfaces of the first electrodes 130, but the invention is not limited thereto. Part of the first bank 222 and part of the second banks 124 fill the gap between the first electrodes 130.

In some embodiments, the thickness of the second banks 124 is greater than the thickness of the first bank 222. For example, the thickness of the second banks 124 is greater than 1 micrometer, and the thickness of the first bank 222 is less than 1 micrometer.

The bank structure 220 has a plurality of openings 0, and each first electrode 130 is located at the bottom of a corresponding opening 0 of the bank structure 220. Two sides of each opening 0 are defined by two corresponding arc surfaces CS of the first bank 222. In this embodiment, the two sides of each opening 0 are defined by two corresponding arc surfaces CS of two adjacent arc surface portions 222b. The other two sides of each opening 0 are defined by the two opposite side walls SW of the two corresponding second banks 124. In each opening 0, the angles 0 between the two corresponding arc surfaces CS and the two opposite side walls SW of the corresponding two second banks 124 are greater than 90 degrees.

In this embodiment, the material of the first bank 222 is different from the material of the second banks 124. For example, the first bank 222 includes a hydrophilic material, and the second banks 124 include a hydrophobic material. In some embodiments, the material of the first bank 222 includes a cured positive photoresist, and the material of the second banks 124 include a cured negative photoresist.

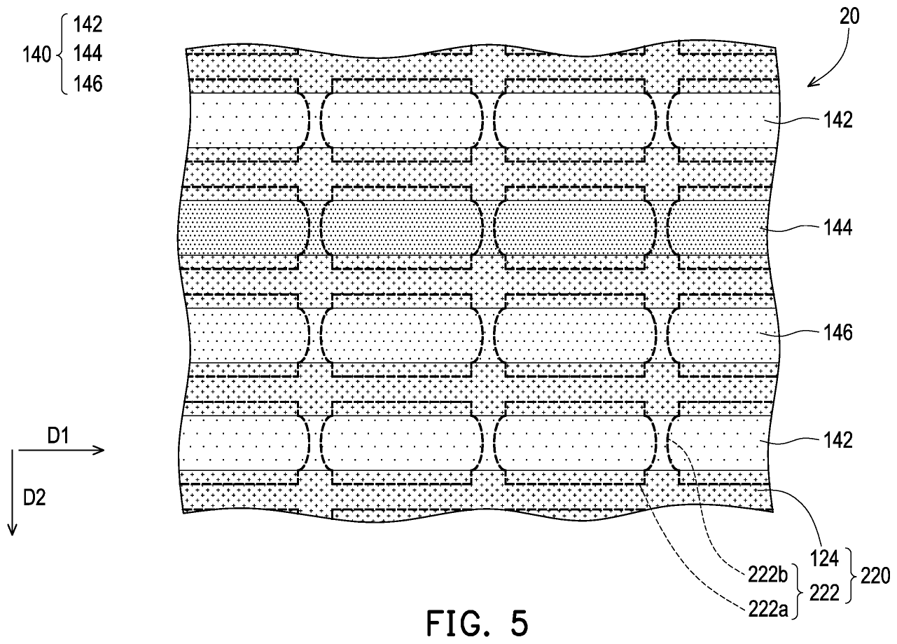

Referring to FIG. 5, a plurality of organic light emitting materials 140 are formed on the first electrode 130. In this embodiment, the organic light-emitting materials 140 are filled in the openings 0 of the bank structure 220.

In this embodiment, the organic light emitting materials 140 include a first organic light emitting material 142, a second organic light emitting material 144, and a third organic light emitting material 146. The first organic light-emitting material 142, the second organic light-emitting material 144, and the third organic light-emitting material 146 extend along the first direction D1, and the organic light-emitting materials 140 between two adjacent second banks 124 have the same color. The first organic light emitting material 142, the second organic light emitting material 144, and the third organic light emitting material 146 are arranged along the second direction D2, and the first organic light emitting material 142, the second organic light emitting material 144, and the third organic light emitting materials 146 arranged along the second direction D2 are separated from each other.

In this embodiment, the first organic light-emitting material 142, the second organic light-emitting material 144, and the third organic light-emitting material 146 extend along the first direction D1, and each of the first organic light-emitting material 142, the second organic light-emitting material 144, and the third organic light-emitting material 146 cross a plurality of the arc surface portions 222b of first bank 222. In this embodiment, since the first bank 222 includes a hydrophilic material, the organic light-emitting materials 140 of the same color can easily cross the first bank 222. At the same time, since the second banks 124 include a hydrophobic material, the organic light emitting materials 140 of different colors cannot easily cross the second banks 124, so that the organic light emitting materials 140 of different colors are not easily mixed with each other.

In this embodiment, the wetting effect of the organic light emitting materials 140 and the bank structure 220 can be improved by the arrangement of the arc surfaces CS. Specifically, with the arrangement of the arc surfaces CS, the problem that the angle between the first bank 122 and the second bank 124 is too small can be improved, thereby avoiding the problem that the organic light emitting materials 140 is difficult to fill the angle between the first bank 122 and the second bank 124.

FIG. 6A to FIG. 6D, the second electrode 150 is formed on the organic light-emitting materials 140. So far, the light-emitting device 2 is substantially completed.

In this embodiment, the second electrode 150 is located on the organic light-emitting materials 140 and on the second banks 124. In some embodiments, at least one of the first electrodes 130 and the second electrode 150 is a transparent electrode, so that the light emitted by the organic light-emitting materials 140 can pass through the first electrodes 130 and/or the second electrode 150.

Based on the above, the arc surfaces CS are beneficial to improve the wetting effect of the organic light-emitting materials 140 and the bank structure 220, thereby increasing the uniformity of the organic light-emitting material 140 and improving the display efficacy of the light-emitting device 2.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light-emitting device, comprising:
a substrate;
an active device layer, located on the substrate;
a bank structure, located on the active device layer, the bank structure includes:
at least one first bank, the at least one first bank has a plurality of arc surfaces, and the at least one first bank comprises a hydrophilic material; and
a plurality of second banks, extending along a first direction, and the plurality of second banks include a hydrophobic material, wherein the at least one first bank partially is overlapping with the plurality of second banks, wherein the bank structure has a plurality of openings, two sides of each opening are defined by two corresponding arc surfaces of the at least one first bank, and the other two sides of each opening are defined by two opposite side walls of two corresponding second banks; and
a plurality of organic light-emitting materials, filled in the plurality of openings of the bank structure.

2. The light-emitting device of claim 1, wherein a material of the at least one first bank includes a cured positive photoresist, and a material of the plurality of second banks includes a cured negative photoresist.

3. The light-emitting device of claim 1, wherein the plurality of organic light-emitting materials include a first organic light-emitting material, a second organic light-emitting material, and a third organic light-emitting material, and the organic light-emitting materials between two adjacent second banks have a same color.

4. The light-emitting device of claim 3, wherein the first organic light-emitting material, the second organic light-emitting material, and the third organic light-emitting material arranged in a second direction are separated from each other.

5. The light-emitting device of claim 1, wherein the at least one first bank is a plurality of first banks, and the plurality of first banks are extending along a second direction, and each of the plurality of first banks is partially overlapping with the plurality of second banks.

6. The light-emitting device of claim 5, wherein opposite sides of each first bank have a plurality of corresponding arc surfaces.

7. The light-emitting device of claim 6, wherein the minimum width of each first bank at the position of the plurality of corresponding arc surfaces is smaller than the minimum width of each first bank at the position overlapping the plurality of second banks.

8. The light-emitting device of claim 1, wherein the at least one first bank is a continuous mesh structure.

9. The light-emitting device of claim 8, wherein the at least one first bank comprises:
a plurality of extension portions, overlapping with the plurality of second banks, and extending along the first direction; and
a plurality of arc surface portions, extending along a second direction, wherein the plurality of arc surface portions have the plurality of arc surfaces.

10. The light-emitting device of claim 9, wherein the plurality of second banks are in contact with top surfaces and side surfaces of the plurality of extension portions.

11. The light-emitting device of claim 1, wherein the thickness of each second bank is greater than the thickness of the at least one first bank.

12. The light emitting device of claim 1, wherein angles between the two corresponding arc surfaces and the two opposite side walls of two corresponding second banks are greater than 90 degrees in each of the openings.

13. The light-emitting device of claim 1, further comprises:
a plurality of first electrodes, electrically connected to the active device layer, wherein each first electrode is located at a bottom of one corresponding opening of the bank structure, and the plurality of organic light-emitting materials are formed on the plurality of first electrodes; and
a second electrode, formed on the plurality of organic light-emitting materials.

14. The light-emitting device of claim 13, wherein a part of the at least one first bank and a part of the plurality of second banks are filled in a gap between the plurality of first electrodes.
